(19) United States
(12) Patent Application Publication
(10) Pub. No.: US 2026/0314437 A1
(43) Pub. Date: Oct. 8, 2026

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Naoki YOSHIMATSU, Fukuoka (JP); Hideo KOMO, Tokyo (JP)

(73) Assignee: Mitsubishi Electric Corporation, Tokyo (JP)

(21) Appl. No.: 19/484,850

(22) PCT Filed: Aug. 3, 2023
(86) PCT No.: PCT/JP2023/028403

§ 371 Date: Nov. 14, 2025

(51) Int. Cl. H10W 70/40; H10W 40/00; H10W 40/20; H10W 40/22; H10W 72/00; H10W 90/00; H10W 90/10

(52) U.S. Cl. CPC H10W 70/421; H10W 40/226; H10W 40/235; H10W 70/461; H10W 70/481; H10W 90/10; H10W 90/736; H10W 90/811; H10W 40/037; H10W 72/07336; H10W 72/884; H10W 90/756

(57) ABSTRACT

A back surface pattern is bonded to a heatsink by solder, a surface of the back surface pattern bonded to the heatsink is located in the same height position as a surface of mold resin facing the heatsink, a first slit for dividing a front surface pattern into a plurality of regions is provided to the front surface pattern, a second slit for dividing the back surface pattern into a plurality of regions is provided to the back surface pattern, and the first slit and the second slit are not overlapped with each other or only a part of the first slit and a part of the second slit are overlapped with each other in a thickness direction of an insulating substrate.

### TECHNICAL FIELD

The present disclosure relates to a semiconductor device and a method of manufacturing the semiconductor device.

### BACKGROUND ART

For example, disclosed in Patent document 1 is a semiconductor device including a plurality of wiring layers (corresponding to a surface pattern), an insulating substrate (corresponding to an insulating layer) to which first back surfaces of the plurality of wiring layers are bonded, a plurality of heat radiation layers (corresponding to a back surface pattern) in which a second main surface is bonded to the insulating substrate, a semiconductor element bonded to any one of the first main surfaces of the plurality of wiring layers, and sealing resin covering the insulating substrate, the plurality of wiring layers, and the semiconductor element. Since the plurality of wiring layers bonded to the surface of the insulating substrate and the plurality of heat radiation layers bonded to the back surface of the insulating substrate are disposed to be overlapped with each other in a thickness direction of the insulating substrate, a difference of a expansion-shrinkage amount of the front surface side and the back surface side of the insulating substrate in accordance with the temperature change is reduced, and a warpage occurring in the insulating substrate is suppressed.

### PRIOR ART DOCUMENTS

### Patent Document(s)

Patent Document 1: International Publication No. 2020/149225

### SUMMARY

### Problem to be Solved by the Invention

However, the technique described in Patent Document 1 does not take a warpage of a product occurring after transfer molding into consideration. Particularly, a slit for division into the plurality of wiring layers on the front surface side of the insulating substrate and a slit for division into the plurality of heat radiation layers on the back surface side are located in the same position in the thickness direction of the insulating substrate. Thus, there is a problem that the whole substrate including the plurality of wiring layers and the plurality of heat radiation layers is easily bended and cracked.

Accordingly, an object of the present disclosure is to provide a technique capable of suppressing a crack of an insulating substrate even when a warpage occurs in a product after transfer molding.

### Means to Solve the Problem

A semiconductor device according to the present disclosure includes: an insulating substrate including an insulating layer, a front surface pattern formed on a front surface of the insulating layer, and a back surface pattern formed on a back surface of the insulating layer; a semiconductor element mounted on the front surface pattern; and sealing resin sealing the insulating substrate and the semiconductor clement while a surface of the back surface pattern on a side opposite to a surface facing the insulating layer is exposed, wherein the back surface pattern is bonded to a heatsink by solder, a surface of the back surface pattern bonded to the heatsink is located in a same height position as a surface of the sealing resin facing the heatsink, a first slit for dividing the front surface pattern into a plurality of regions is provided to the front surface pattern, a second slit for dividing the back surface pattern into a plurality of regions is provided to the back surface pattern, and the first slit and the second slit are not overlapped with each other or only a part of the first slit and a part of the second slit are overlapped with each other in a thickness direction of the insulating substrate.

### Effects of the Invention

According to the present disclosure, a part where the first slit on a side of the front surface of the insulating substrate and the second slit on a side of the back surface thereof is reduced in the thickness direction of the insulating substrate. Thus, a crack of the insulating substrate can be suppressed even when a warpage of a product occurs after transfer molding.

These and other objects, features, aspects and advantages of the present disclosure will become more apparent from the following detailed description when taken in conjunction with the accompanying diagrams.

### BRIEF DESCRIPTION OF DRAWINGS

FIG. 1 is a cross-sectional view of a semiconductor device according to an embodiment.

FIG. 2 is a flow chart illustrating a method of manufacturing the semiconductor device according to the embodiment.

FIG. 3 is a cross-sectional view illustrating a die bonding process according to the embodiment.

FIG. 4 is a cross-sectional view illustrating a lead bonding process according to the embodiment.

FIG. 5 is a cross-sectional view illustrating a wire bonding process according to the embodiment.

FIG. 6 is a cross-sectional view illustrating a molding process according to the embodiment.

FIG. 7 is a cross-sectional view illustrating a solder mounting process according to the embodiment.

FIG. 8 is a cross-sectional view of a semiconductor device for explaining occurrence of a solder void according to the embodiment.

FIG. 9 is a bottom view illustrating an example of an insulating substrate included in the semiconductor device according to the embodiment.

FIG. 10 is a bottom view illustrating another example of the insulating substrate included in the semiconductor device according to the embodiment.

FIG. 11 is an enlarged cross-sectional view around a second slit provided to a back surface pattern included in the semiconductor device according to the embodiment.

FIG. 12 is an enlarged cross-sectional view around a second slit provided to a back surface pattern included in a semiconductor device according to a modification example of the embodiment.

FIG. 13 is a cross-sectional view of a semiconductor device for explaining occurrence of a solder void according to a related technique.

### DESCRIPTION OF EMBODIMENT(S)

### Embodiment

### Configuration of Semiconductor Device

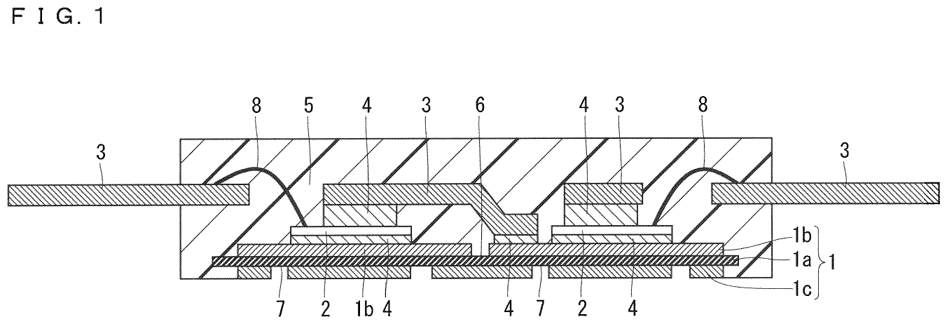

An embodiment is described hereinafter using the diagrams. FIG. 1 is a cross-sectional view of a semiconductor device according to the embodiment.

As illustrated in FIG. 1, the semiconductor device includes an insulating substrate 1, a plurality of semiconductor elements 2, a plurality of lead frames 3, and mold resin 5 as sealing resin.

The insulating substrate 1 includes an insulating layer 1a, a front surface pattern 1b, and a back surface pattern 1c. The insulating layer 1a is formed of ceramics. The front surface pattern 1b is made of metal such as copper or aluminum, and is formed on a front surface of the insulating layer 1a. A first slit 6 for dividing the front surface pattern 1b into a plurality of regions is provided to the front surface pattern 1b. The back surface pattern 1c is made of metal such as copper or aluminum, and is formed on a back surface of the insulating layer 1a. A second slit 7 for dividing the back surface pattern 1c into a plurality of regions is provided to the back surface pattern 1c. The second slit 7 is formed into a lattice-like shape in a thickness direction of the insulating substrate 1. The second slit 7 is formed to surround the semiconductor element 2 in the thickness direction of the insulating substrate 1.

The plurality of semiconductor elements 2 are mounted on the front surface pattern 1b via solder 4. The plurality of semiconductor elements 2 are elements functioning as switching elements or rectifier elements, for example. The switching element is an insulated gate bipolar transistor (IGBT) or a metal oxide semiconductor field effect transistor (MOSFET), for example. The rectifier element is a diode element.

A material constituting the plurality of semiconductor elements 2 is silicon (Si), for example. A material constituting the plurality of semiconductor elements 2 is not limited to silicon; however, also applicable is a wide bandgap semiconductor material such as silicon carbide (SiC), gallium nitride (GaN), or diamond (C), for example. The wide bandgap semiconductor material is a material having wider bandgap than Si. The plurality of semiconductor elements 2 made of the wide bandgap semiconductor material can perform an operation using large current and an operation under a high temperature environment. Thus, the material constituting the plurality of semiconductor elements 2 is preferably a wide bandgap semiconductor material.

A material of the plurality of lead frames 3 is copper, for example. The plurality of lead frames 3 are bonded to a surface electrode of the semiconductor element 2 by the solder 4, are bonded to the front surface pattern 1b by the solder 4, and are connected to a wire pad of the semiconductor element 2 via an aluminum wire 8.

The mold resin 5 is epoxy system thermoset resin, for example. The mold resin 5 seals the insulating substrate 1 and the semiconductor element 2 while exposing a surface of the back surface pattern 1c on a side opposite to a surface thereof facing the insulating layer 1a.

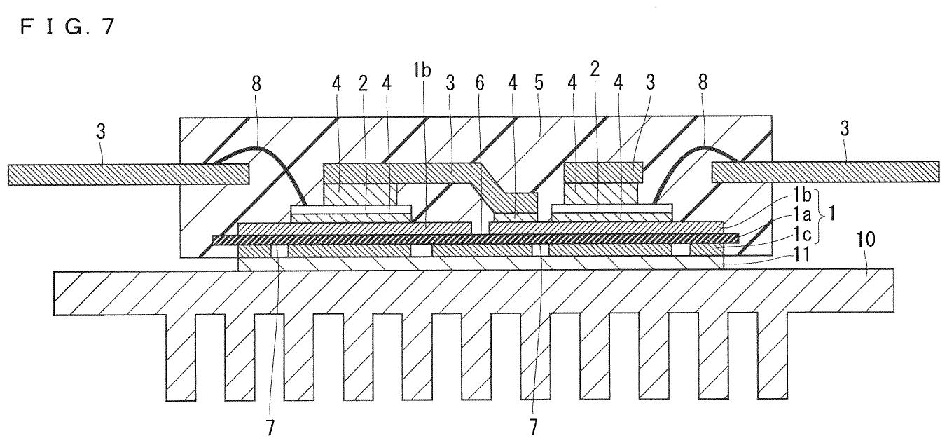

Herein, the semiconductor device is bonded to the heatsink 10 (refer to FIG. 7). However, the surface of the back surface pattern 1c bonded to the heatsink 10 is located in the same height position as a surface of the mold resin 5 facing the heatsink 10. Thus, a level difference does not occur between the back surface pattern 1c and the mold resin 5.

### Method of Manufacturing Semiconductor Device

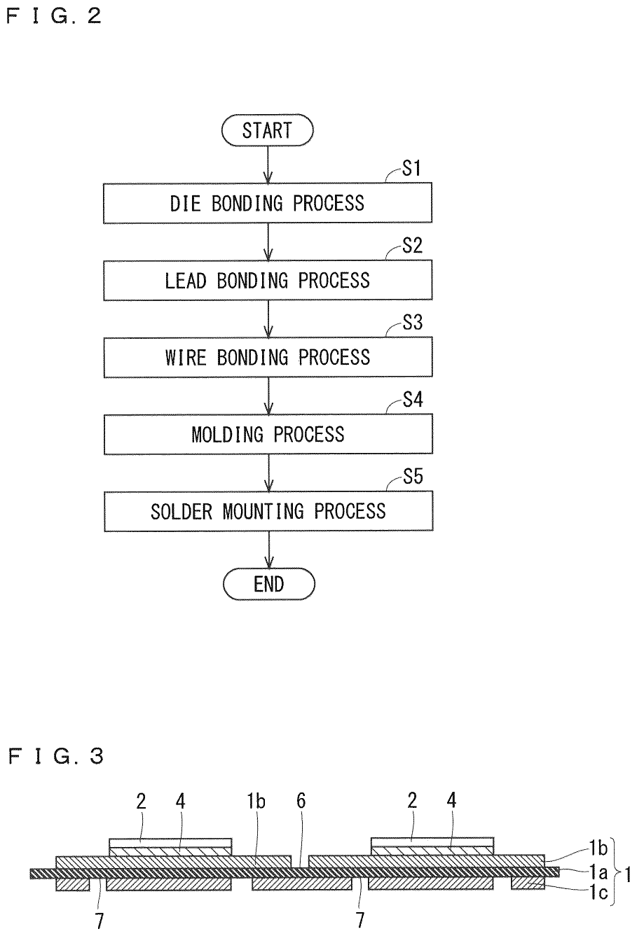

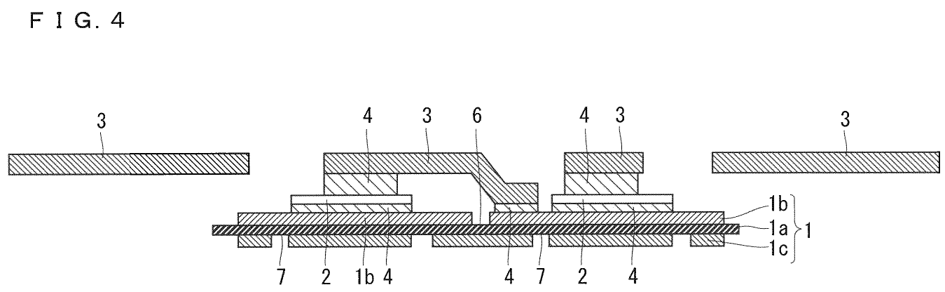

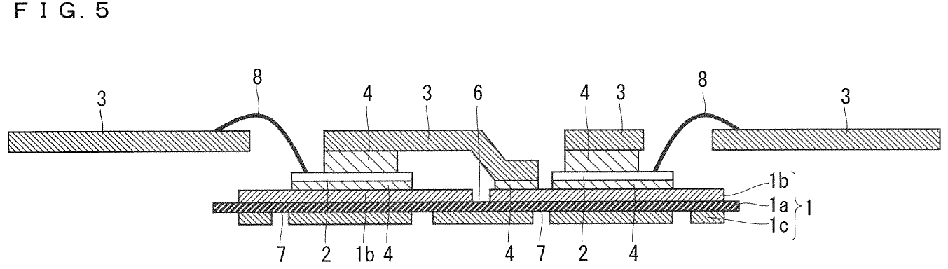

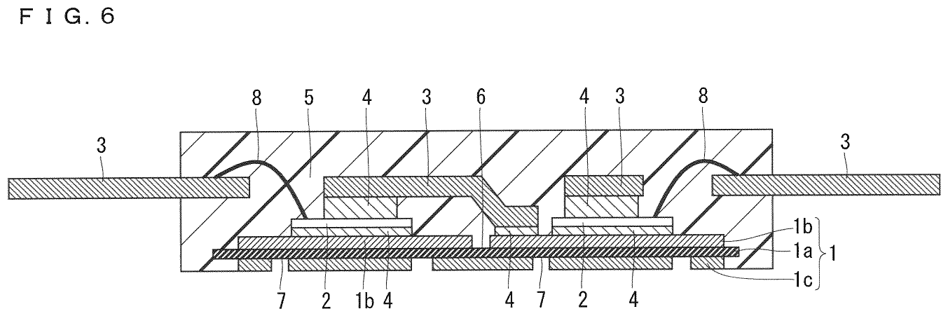

A method of manufacturing a semiconductor device is described next using FIG. 2 to FIG. 7. FIG. 2 is a flow chart illustrating the method of manufacturing the semiconductor device according to the embodiment. FIG. 3 is a cross-sectional view illustrating a die bonding process according to the embodiment. FIG. 4 is a cross-sectional view illustrating a lead bonding process according to the embodiment. FIG. 5 is a cross-sectional view illustrating a wire bonding process according to the embodiment. FIG. 6 is a cross-sectional view illustrating a molding process according to the embodiment. FIG. 7 is a cross-sectional view illustrating a solder mounting process according to the embodiment. Only a major process in the method of manufacturing the semiconductor device is extracted and simply illustrated in FIG. 2.

Firstly, as illustrated in FIG. 2 and FIG. 3, in Step S1, the solder 4 is disposed on the front surface pattern 1b of the insulating substrate 1, the semiconductor element 2 is mounted thereon, and the solder 4 is melted by reflow, for example, to bond the semiconductor element 2 to the insulating substrate 1. Although the embodiment exemplifies bonding by the solder 4, the configuration is not limited thereto. Sintering by silver or copper may be performed.

Next, as illustrated in FIG. 2 and FIG. 4, the solder 4 is disposed on the surface electrode of the semiconductor element 2 and the front surface pattern 1b, the lead frame 3 is disposed thereon, and the solder 4 is melted by reflow, for example, to bond the surface electrode of the semiconductor element 2 and the lead frame 3 and bond the front surface pattern 1b and the lead frame 3.

Next, as illustrated in FIG. 2 and FIG. 5, in Step S3, a wire pad of the semiconductor element 2 and a signal terminal of the lead frame 3 are bonded by ultrasonic waves with the aluminum wire 8 having a diameter of approximately 100 to 400 μm.

Next, as illustrated in FIG. 2 and FIG. 6, in Step S4, a wire bonding completed product and tablet-like resin as a material of the mold resin 5 are set in a lower mold of a mold tool not shown in the diagrams, an upper mold is closed, and the resin is turned into a gel at high temperature of approximately 180° C. to be flowed into a space (cavity) in the mold tool through a runner and a gate with pressure. The gelled resin is hardened again at high temperature and becomes the mold resin 5 having the same shape as the cavity. This is taken out from the mold tool.

Next, as illustrated in FIG. 2 and FIG. 7, in Step S5, solder 11 and the semiconductor device as the mold completed product are disposed on the heatsink 10 as a heat radiation member, and the solder 11 is melted by reflow, for example, to bond the semiconductor device and the heatsink 10.

In the processes described above, the insulating substrate 1 is exposed under high temperature in the die bonding process (Step S1), the lead bonding process (Step S2), the molding process (Step S4), and the solder mounting process (Step S5), Ceramics constituting the insulating layer 1a of the insulating substrate 1 is a brittle material, thus has low tolerance against bending. Thus, it is important to prevent a warpage as much as possible in each process.

However, since conductivity and heat radiation properties are functionally required in the insulating substrate 1, the front surface pattern 1b and the back surface pattern 1c are bonded to the front surface and the back surface, respectively, and patterning is performed. Since copper has excellent performance, copper is generally used for the front surface pattern 1b and the back surface pattern 1c. Since copper is a material having high rigidity and there is a difference of the linear expansion coefficient between copper and ceramics, when balance is uneven between the side of the front surface and the side of the back surface of the insulating layer 1a, a warpage occurs in accordance with temperature change. The front surface pattern 1b is generally divided into a plurality of regions by the first slit 6, and has lower rigidity than the front surface pattern 1b with no division. The second slit 7 is provided to the back surface pattern 1c to reduce the rigidity to achieve a balance with the front surface pattern 1b having decreasing rigidity.

Since the back surface pattern 1c serves as a heat radiation route transmitting heat generated from the semiconductor element 2 to the heatsink 10, the second slit 7 is not provided immediately below the semiconductor element 2, but is provided around the area immediately below the semiconductor element 2. That is to say, the second slit 7 is provided to surround a position of the front surface pattern 1b corresponding to a position where the semiconductor element 2 is mounted.

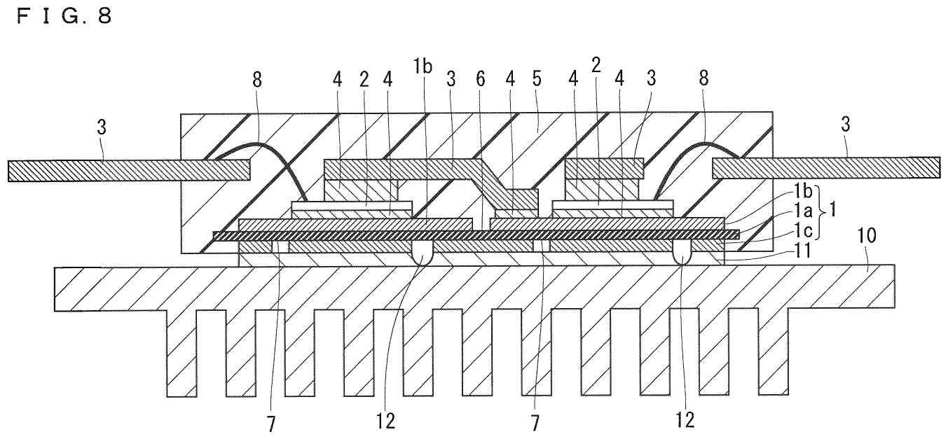

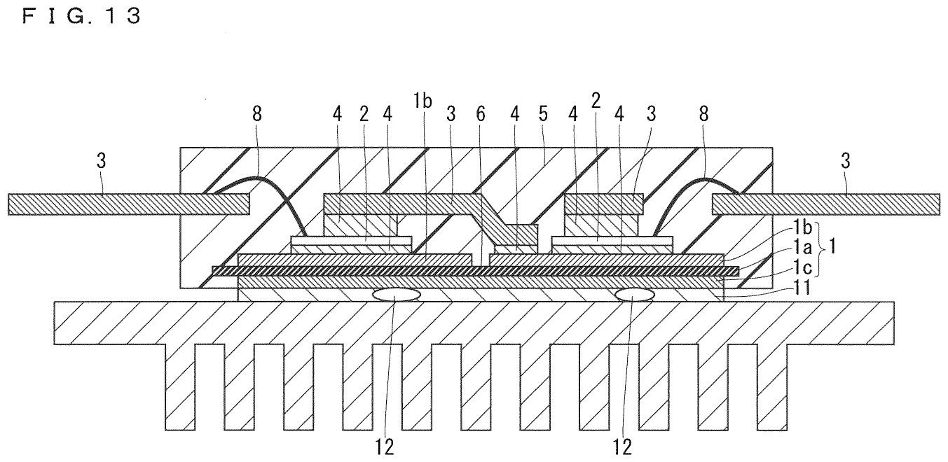

Next, a solder void 12 occurring in the solder 11 is described. FIG. 13 is a cross-sectional view of a semiconductor device for explaining occurrence of the solder void 12 according to a related technique. FIG. 8 is a cross-sectional view of a semiconductor device for explaining occurrence of the solder void 12 according to the embodiment.

When air is drawn into the solder 11 in solder bonding of the semiconductor device to the heatsink 10 and is left in the solder 11, the air causes the solder void 12 blocking heat radiation as illustrated in FIG. 13. The solder void 12 comes out more easily as an area of a bonding member bonded to the heatsink 10 decreases, but hardly comes out from a bonding material having a large area such as the insulating substrate 1. However, heat radiation mainly occurs immediately below semiconductor element 2 in the insulating substrate 1 having the large area. Thus, as illustrated in FIG. 8, when the solder void 12 can be discharged to the second slit 7 provided to the back surface pattern 1c, influence on the heat radiation properties is reduced, and the semiconductor device having high heat radiation properties can be achieved. Since the position of occurrence of the solder void 12 is unspecified, an effect of discharging the solder void 12 from immediately below the semiconductor element 2 is further enhanced by making reduced-pressure atmosphere and shaking the semiconductor device.

It is necessary to ensure that the second slit 7 is not filled with the mold resin 5 to discharge the solder void 12 to the second slit 7 as described above. When the wire bonding completed product is set in the lower mold of the mold tool, positioning thereof needs to be performed by the lead frame 3. This is because the processing is performed to prevent a gap between the lead frame 3 and the mold tool so that resin is not leaked when the upper mold and the lower mold are closed and the resin is injected into the cavity. However, slight misalignment occurs by accuracy of a jig used for bonding the lead frame 3 and the insulating substrate 1 by the solder 4 and a clearance. Thus, it is possible to make the insulating substrate 1 have contact with only a surface of the lower mold, but it is difficult to fit the back surface pattern 1c with no gap around the back surface pattern 1c.

Thus, when the back surface pattern 1c is not completely divided as with the front surface pattern 1b but only an outermost periphery thereof is connected, flow of the mold resin 5 into the second slit 7 can be suppressed. It is preferable that a width of a part of the connected outermost periphery of the back surface pattern 1c is approximately 1 mm or more although depending on pressure in injection of the resin and flatness of the insulating substrate 1.

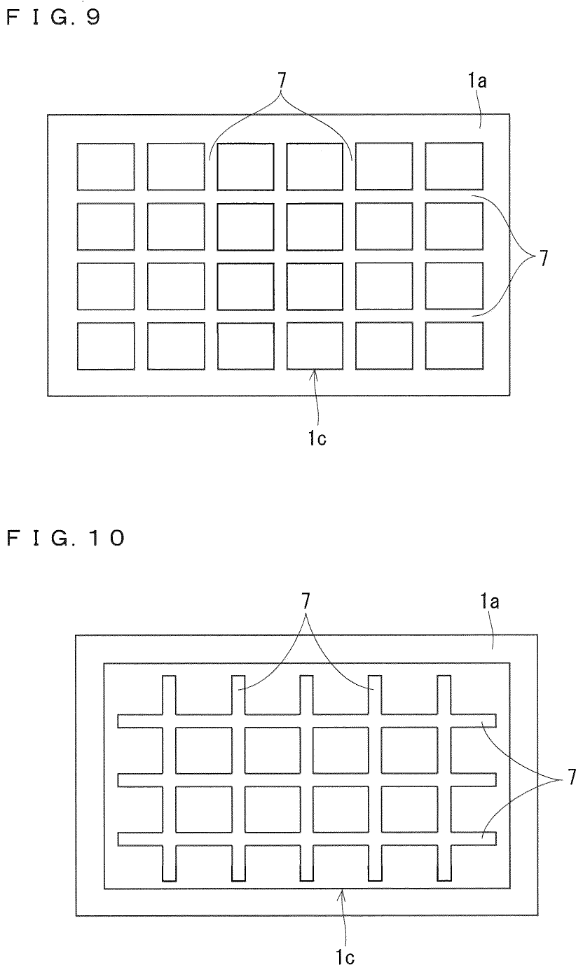

FIG. 9 is a bottom view illustrating an example of the insulating substrate 1 included in the semiconductor device according to the embodiment. FIG. 10 is a bottom view illustrating another example of the insulating substrate 1 included in the semiconductor device according to the embodiment. As illustrated in FIG. 9, when the outermost periphery of the back surface pattern 1c is not connected, flow of the resin from the outermost periphery of the back surface pattern 1c needs to be suppressed by pressing a sheet having cushioning properties, for example, against the back surface pattern le in transfer molding. However, it is more difficult to suppress the flow thereof as the thickness of the back surface pattern 1c increases. As illustrated in FIG. 10, since the back surface pattern 1c is connected in the outermost periphery of the back surface pattern 1c, the sheet having the cushioning properties, for example, is unnecessary, and the flow of the resin can be suppressed without limitation on the thickness of the back surface pattern 1c.

The suppression of the warpage of the single insulating substrate 1 is as described above. It is also important to suppress a crack of the insulating substrate 1 also in a case where a warpage of a product occurs after the transfer molding. The warpage of the product after the transfer molding is caused by a difference of expansion and shrinkage between the mold resin 5 and the insulating substrate 1. Accordingly, it is important to bring the linear expansion coefficient of the mold resin 5 and the insulating substrate 1 close to each other.

A major component for determining mechanical characteristics such as the linear expansion coefficient of the mold resin 5 is resin and a filler, and the linear expansion coefficient can be reduced by increasing a ratio of the filler. However, when the ratio of the filler is too high, flowability of the resin is deteriorated in the transfer molding. Thus, the ratio of the filler is adjusted so that the linear expansion coefficient realistically ranges from 100 ppm/° C. to 20 ppm/° C.

In the meanwhile, when the insulating substrate 1 is a composite body of ceramics (the insulating layer 1a) and copper patterns on front and back surfaces (the front surface pattern 1b and the back surface pattern 1c), the linear expansion coefficient can be adjusted by changing the thickness thereof. Silicon nitride, for example, is mainly used for ceramics, the linear expansion coefficient thereof is 3.5 ppm/° C., and the linear expansion coefficient of the copper pattern is 16.7 ppm/° C. The linear expansion coefficient of the composite body thereof takes a value therebetween, and which one the linear expansion coefficient thereof is closer to is determined by the ratio of rigidity of each material. The ratio of the rigidity can be approximated by a ratio of a product of each volume and an elastic coefficient.

The mold resin 5 has the linear expansion coefficient of 10 ppm/° C., which is a value intermediate between each linear expansion coefficient of silicon nitride and copper, and it is sufficient that each rigidity is equivalent to each other. An elastic coefficient of silicon nitride is 300 GPa and an elastic coefficient of copper is 117 GPa. When a thickness of silicon nitride is t1, a thickness of copper is t2, and an area ratio of copper is approximately 90% although varied depending on a design specification, 300×t1×1=117×t2×0.9 and t2=300/(117×0.9)×t1=2.85×t1 are established.

That is to say, when a total thickness of the copper patterns on the front and back surfaces is 2.8 times as large as that of ceramics, and the copper patterns on the front and back surfaces have the same thickness, that is 1.4 times as large as ceramics, the linear expansion coefficient is approximately 10 ppm/° C. When the thickness of the copper pattern is further increased from this, the linear expansion coefficient can be larger than 10 ppm/° C. The linear expansion coefficient can be infinitely brought close to that of copper in theory by making the component be copper rich. However, when a manufactural limitation on the insulating substrate 1 and a size limitation on the semiconductor device are considered, an upper limit of the thickness of the copper patterns on the front and back surfaces is approximately 3 to 3.5 times as large as the thickness of ceramics.

A warpage of the single insulating substrate 1 and a warpage of the product after transfer molding cannot be prevented. Accordingly, it is also important to make the insulating layer 1a made up of ceramics as the brittle material resistant to cracking.

When the slit is not provided to the front surface pattern 1b and the back surface pattern 1c, the front surface pattern 1b and the back surface pattern 1c protect the insulating layer 1a and have resistance to bending. In the meanwhile, when the slit is provided, bending occurs in a part including the first slit 6 (or the second slit 7) and a crack easily occurs by reason that there is a large difference of rigidity between a part including the front surface pattern 1b (or the back surface pattern le) and the part including the first slit 6 (or the second slit 7). When the first slit 6 and the second slit 7 are overlapped with each other in the thickness direction of the insulating substrate 1, the crack occurs more easily.

In order to solve such a problem, the first slit 6 and the second slit 7 are not overlapped with each other or only a part of the first slit 6 and a part of the second slit 7 are overlapped with each other in the thickness direction of the insulating substrate 1 in the embodiment, Described hereinafter is the case where only a part of the first slit 6 and a part of the second slit 7 are overlapped with each other. Both the first slit 6 and the second slit 7 have at least one straight part. When a part of the first slit 6 and a part of the second slit 7 are overlapped with each other in the thickness direction of the insulating substrate 1, a length of a part where a predetermined straight part of the first slit 6 and a predetermined straight part of the second slit 7 are overlapped with each other is 50% or less of a total of a length of the predetermined straight part of the first slit 6 and a length of the predetermined straight part of the second slit 7, In FIG. 9 and FIG. 10, the second slit 7 is formed into a lattice-like shape, and includes a plurality of straight parts.

In this manner, since the part where the first slit 6 and the second slit 7 are overlapped with each other is reduced, achievable is the structure suppressing a crack of the insulating substrate 1 even when a warpage of a product occurs after transfer molding.

### Effect

As described above, the semiconductor device according to the embodiment includes: the insulating substrate 1 including the insulating layer 1a, the front surface pattern 1b formed on the front surface of the insulating layer 1a, and the back surface pattern 1c formed on the back surface of the insulating layer 1a; the semiconductor element 2 mounted on the front surface pattern 1b; and the mold resin 5 sealing the insulating substrate 1 and the semiconductor element 2 while the surface of the back surface pattern 1c on the side opposite to the surface facing the insulating layer 1a is exposed. The back surface pattern 1c is bonded to the heatsink 10 by the solder 11, the surface of the back surface pattern 1c bonded to the heatsink 10 is located in the same height position as the surface of the mold resin 5 facing the heatsink 10, the first slit 6 for dividing the front surface pattern 1b into the plurality of regions is provided to the front surface pattern 1b, the second slit 7 for dividing the back surface pattern le into the plurality of regions is provided to the back surface pattern 1c, and the first slit 6 and the second slit 7 are not overlapped with each other or only a part of the first slit 6 and a part of the second slit 7 are overlapped with each other in the thickness direction of the insulating substrate 1.

Specifically, both the first slit 6 and the second slit 7 have at least one straight part. The length of a part where the predetermined straight part of the first slit 6 and the predetermined straight part of the second slit 7 are overlapped with each other is 50% or less of the total of the length of the predetermined straight part of the first slit 6 and the length of the predetermined straight part of the second slit 7 in the thickness direction of the insulating substrate 1.

Accordingly, the part where the first slit 6 on the side of the front surface of the insulating substrate 1 and the second slit 7 on the side of the back surface thereof are overlapped with each other is reduced. Thus, the crack of the insulating substrate 1 can be suppressed even when the warpage of the product occurs after transfer molding. According to such a configuration, the semiconductor device can be used for a long time.

Since the mold resin S does not fill the second slit 7, the solder void 12 remaining in the solder 4 can be discharged to the second slit 7 in the solder bonding. Accordingly, the heat generated from the semiconductor element 2 can be efficiently radiated.

Since the back surface pattern le is connected in the outermost periphery of the back surface pattern 1c, the flow of the mold resin 5 into the second slit 7 at the time of transfer molding can be suppressed.

Since the second slit 7 surrounds the position of the front surface pattern 1b corresponding to the position where the semiconductor element 2 is mounted, the solder void 12 hardly occurs immediately below the semiconductor element 2. Accordingly, the heat radiation properties of the semiconductor device are improved.

The thickness of both the front surface pattern 1b and the back surface pattern 1c is 1.4 time or more as large as the thickness of the insulating layer 1a. Accordingly, the effect of suppressing the warpage of the insulating substrate 1 is increased, and furthermore, the effect of suppressing the warpage of the product after transfer molding is also increased.

The semiconductor element 2 is the wide bandgap semiconductor element, thus can be operated under high temperature compared with an Si semiconductor element. However, the heat radiation effect of the semiconductor device can be increased as described above, increase of the temperature of the semiconductor element 2 can be suppressed. Accordingly, loss of the semiconductor element 2 can be suppressed.

Although the MOSFET made of SiC can be operated under high temperature, a loss is extremely deteriorated at high temperature. Thus, the MOSFET made of SiC is preferably used under low temperature as much as possible. The heat generated from the semiconductor element 2 is efficiently transmitted to the heatsink 10 and the increase of the temperature of the semiconductor element 2 can be suppressed. Thus, the configuration of the semiconductor device according to the embodiment is particularly appropriate for the MOSFET made of SiC.

### Modification Example of Embodiment

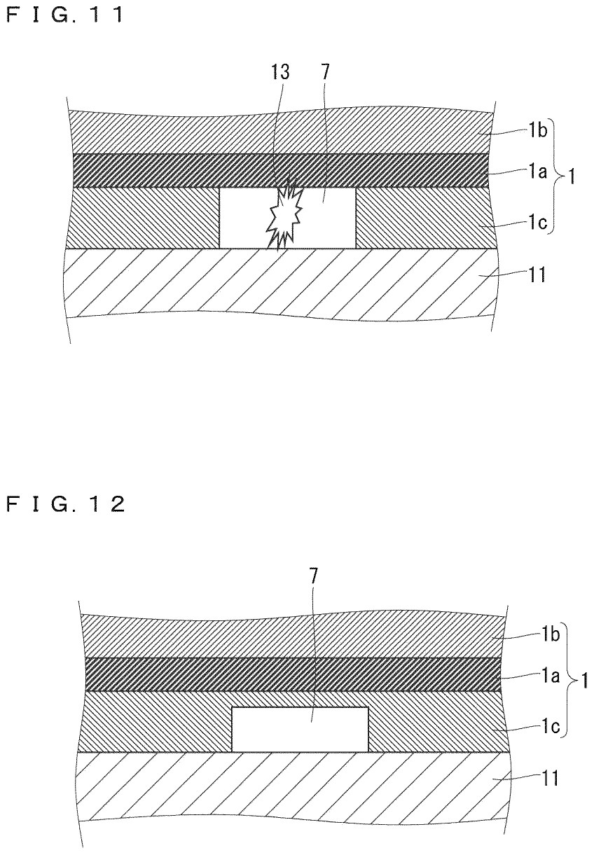

A modification example of the embodiment is described next. FIG. 11 is an enlarged cross-sectional view around the second slit 7 provided to the back surface pattern 1c included in the semiconductor device according to the embodiment. FIG. 12 is an enlarged cross-sectional view around the second slit 7 provided to the back surface pattern 1c included in the semiconductor device according to the modification example of the embodiment.

High voltage may be applied to the sides of the front surface and the back surface of the insulating substrate 1 in the semiconductor device in some cases. Voltage of approximately 400 V to 1000 V is applied in a case of an electrical automobile, for example. As illustrated in FIG. 11, in a case where the second slit 7 passes through the back surface pattern 1c and is formed to reach the back surface of the insulating layer 1a, when the solder void 12 (refer to FIG. 8) is located in the second slit 7, the solder void 12 has contact with the insulating layer 1a, and there is a possibility that partial electrical discharge 13 occurs from the insulating layer 1a.

In order to avoid this problem, as illustrated in FIG. 12, the second slit 7 does not pass through the back surface pattern 1c and is not formed to reach the back surface of the insulating layer 1a in the modification example of the embodiment. That is to say, the back surface pattern 1c is firmly attached to the back surface of the insulating layer 1a also in the position where the second slit 7 is provided.

A method of manufacturing the insulating substrate 1 is described next. There are a method of attaching the back surface pattern 1c in which the second slit 7 is formed by punching in a press work, for example, to the insulating layer 1a and a method of forming the second slit 7 by melting copper and performing patterning by etching processing after the back surface pattern le in which the second slit 7 is not formed is attached, and the latter manufacturing method is generally adopted in many cases.

A part of the back surface pattern 1c in which the second slit 7 is not formed is masked, and an etching solution is sprayed to only a part thereof in which the second slit 7 is formed to melt the part thereof to perform patterning. Although the insulating layer 1a is normally exposed in an etched part, the second slit 7 is formed by half etching of stop etching in a middle of the insulating substrate 1 in the thickness direction in the etching on the back surface pattern 1c. Thus, the insulating layer 1a is not exposed to the etched part. As a result, since the solder void 12 does not contact with the insulating layer 1a, occurrence of the partial electrical discharge 13 can be suppressed.

Although the present disclosure is described above in detail, the foregoing description is in all aspects illustrative and does not restrict the disclosure. It is therefore understood that numerous modification examples not exemplified can be devised.

Each embodiment can be arbitrarily combined, or each embodiment can be appropriately varied or omitted.

### EXPLANATION OF REFERENCE SIGNS

1 insulating substrate, 1a insulating layer, 1b front surface pattern, 1c back surface pattern, 2 semiconductor element, 5 mold resin, 6 first slit, 7 second slit, 10 heatsink, 11 solder.

1. A semiconductor device, comprising:
an insulating substrate including an insulating layer, a front surface pattern formed on a front surface of the insulating layer, and a back surface pattern formed on a back surface of the insulating layer;
a semiconductor element mounted on the front surface pattern; and
sealing resin sealing the insulating substrate and the semiconductor element while a surface of the back surface pattern on a side opposite to a surface facing the insulating layer is exposed, wherein
the back surface pattern is bonded to a heatsink by solder,
a surface of the back surface pattern bonded to the heatsink is located in a same height position as a surface of the sealing resin facing the heatsink,
a first slit for dividing the front surface pattern into a plurality of regions is provided to the front surface pattern,
a second slit for dividing the back surface pattern into a plurality of regions is provided to the back surface pattern, and
the first slit and the second slit are not overlapped with each other or only a part of the first slit and a part of the second slit are overlapped with each other in a thickness direction of the insulating substrate.

2. The semiconductor device according to claim 1, wherein
the sealing resin does not fill the second slit.

3. The semiconductor device according to claim 1, wherein
the back surface pattern is connected in an outermost periphery of the back surface pattern.

4. The semiconductor device according to claim 1, wherein
the second slit surrounds a position of the front surface pattern corresponding to a position where the semiconductor element is mounted.

5. The semiconductor device according to claim 1, wherein
both the first slit and the second slit include at least one straight part, and
a length of a part where the straight part which is predetermined of the at least one straight part of the first slit and the straight part which is predetermined of the at least one straight part of the second slit are overlapped with each other is 50% or less of a total of a length of the straight part which is predetermined of the first slit and a length of the straight part which is predetermined of the second slit in the thickness direction of the insulating substrate.

6. The semiconductor device according to claim 1, wherein
a thickness of both the front surface pattern and the back surface pattern is 1.4 time or more as large as a thickness of the insulating layer.

7. The semiconductor device according to claim 1, wherein
the second slit does not pass through the back surface pattern, and is not formed to reach the back surface of the insulating layer.

8. The semiconductor device according to claim 1, wherein
the semiconductor element is a wide bandgap semiconductor.

9. A method of manufacturing the semiconductor device according to claim 7, wherein
the second slit is formed by half etching of stop etching in a middle of the insulating substrate in the thickness direction in etching on the back surface pattern.
